(19) United States
(12) Patent Application Publication
(10) Pub. No.: US 2026/0177924 A1
(43) Pub. Date: Jun. 25, 2026

(54) SUBSTRATE PROCESSING METHOD, SUBSTRATE PROCESSING APPARATUS, AND STORAGE MEDIUM

(71) Applicant: Tokyo Electron Limited, Tokyo (JP)

(72) Inventor: Hiroki SAKURAI, Koshi City (JP)

(21) Appl. No.: 19/421,234

(22) Filed: Dec. 16, 2025

(30) Foreign Application Priority Data
Dec. 24, 2024 (JP) 2024-227956

(51) Int. Cl. G03F 7/42; G01K 3/00; G01K 13/02; H10P 50/68

(52) U.S. Cl. CPC G03F 7/422; G01K 3/005; G01K 13/026; H10P 50/68

(57) ABSTRACT

A substrate processing method is performed by a substrate processing apparatus, the apparatus including: a substrate holder configured to hold a substrate; a fluid supply configured to supply a fluid containing water vapor or mist; a processing liquid supply configured to supply a processing liquid containing sulfuric acid; a nozzle configured to mix and discharge the fluid and the processing liquid to the substrate; and a temperature measurer configured to measure a temperature of the processing liquid, and the method including: a processing liquid discharge process of supplying the processing liquid from the processing liquid supply to the nozzle and discharging the processing liquid to the substrate; and a mixed fluid discharge process of supplying the fluid from the fluid supply to the nozzle and discharging a mixed fluid of the fluid and the processing liquid to the substrate, when the temperature of the processing liquid reaches a specified temperature.

### CROSS-REFERENCE TO RELATED APPLICATION

This application is based upon and claims the benefit of priority from Japanese Patent Application No. 2024-227956, filed on Dec. 24, 2024, the entire content of which is incorporated herein by reference.

### TECHNICAL FIELD

The present disclosure relates to a substrate processing method, a substrate processing apparatus, and a storage medium.

### BACKGROUND

In a known technique for a manufacturing process of semiconductor devices, sulfuric acid hydrogen peroxide mixture (SPM) is supplied to a substrate, such as a semiconductor wafer, to remove a removal target material such as a resist film from the substrate. Patent Document 1 discloses that, in order to improve processing efficiency, an SPM is mixed with pure water vapor and then supplied to a substrate.

### PRIOR ART DOCUMENT

### Patent Document

Patent Document 1: Japanese Patent Application Publication No. 2023-087757

### SUMMARY

A substrate processing method is performed by a substrate processing apparatus, the apparatus including: a substrate holder configured to hold a substrate; a fluid supply configured to supply a fluid containing pressurized pure water vapor or mist; a processing liquid supply configured to supply a processing liquid containing at least sulfuric acid; a nozzle configured to mix and discharge the fluid and the processing liquid to the substrate; and a temperature measurer configured to measure a temperature of the processing liquid, and the method including: a processing liquid discharge process of supplying the processing liquid from the processing liquid supply to the nozzle and discharging the processing liquid to the substrate; and a mixed fluid discharge process of supplying the fluid from the fluid supply to the nozzle and discharging a mixed fluid of the fluid and the processing liquid to the substrate, when the temperature of the processing liquid reaches a specified temperature.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1A is a schematic plan view showing an overall configuration of a substrate processing system, which is an embodiment of a substrate processing apparatus.

FIG. 1B is a schematic plan view showing an example configuration of a processing unit incorporated in the substrate processing system of FIG. 1A.

FIG. 2 is a schematic side view of the substrate processing apparatus of FIG. 1A.

FIG. 3 is a view showing a structure of a nozzle for discharging an SPM, and is a cross-sectional view obtained by cutting the nozzle along a plane orthogonal to a longitudinal direction thereof.

FIG. 4 is a cross-sectional view of the nozzle taken along line IV-IV in FIG. 3.

FIG. 5 is a cross-sectional view of the nozzle taken along line V-V in FIG. 3.

FIG. 6 is a schematic bottom plan view of the nozzle shown in FIGS. 3 to 5.

FIG. 7 is a diagram showing an example of a piping system for supplying an SPM and water vapor to a nozzle for discharging the SPM.

FIG. 8 is a flowchart showing an example of a series of processes performed on a single wafer.

FIG. 9 is a flowchart showing an example of detailed procedures for an SPM process shown in FIG. 8.

FIG. 10 is a schematic side view showing an example of a state in which an SPM liquid is being discharged from a nozzle.

FIG. 11 is a schematic side view showing an example of a state in which a mixed fluid of an SPM liquid and vapor is being discharged from a nozzle.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Below, detailed description of forms (hereinafter referred to as “embodiments”) for implementing a substrate processing apparatus (substrate processing system) according to the present disclosure and a substrate processing method performed using the same will be provided with reference to the drawings. However, the present disclosure is not limited to these embodiments. Further, various embodiments can be combined as appropriate as long as contents of processing are not incompatible with one another. In the following embodiments, the same components are denoted by the same reference numerals, and redundant description thereof will be omitted.

In the following embodiments, expressions such as “constant,” “orthogonal,” “perpendicular,” and “parallel” may be used, but these expressions do not necessarily mean “constant,” “orthogonal,” “perpendicular,” or “parallel” in their strict sense. In other words, the above expressions allow for deviations due to, for example, manufacturing accuracy and installation accuracy.

Further, for ease of understanding, the drawings referenced below may refer to a Cartesian coordinate system in which mutually orthogonal X-axis directions, Y-axis directions, and Z-axis directions are defined and a positive Z-axis direction is defined as a vertically upward direction. Furthermore, a direction of rotation about a vertical axis may be referred to as a θ direction.

In a process of manufacturing a semiconductor device, a resist film is formed in a predetermined pattern on a target film formed on a substrate such as a semiconductor wafer, and processes such as etching and ion implantation are performed on the target film by using the resist film as a mask. After the processes, the unnecessary resist film is removed from the wafer.

As a method of removing the resist film, an SPM process is used. The SPM process is performed by supplying a high-temperature sulfuric acid-hydrogen peroxide mixture (SPM) liquid, which is obtained by mixing sulfuric acid and hydrogen peroxide, to the resist film. Further, efficiency of the SPM process can be improved by using a mixed fluid of vapor of pressurized pure water (deionized water) (hereinafter simply referred to as “vapor”) and the SPM liquid.

In addition, the substrate processing apparatus of the present disclosure is also applicable to liquid processing other than the SPM process. Specifically, the substrate processing apparatus of the present disclosure is applicable to liquid processing using a processing liquid containing at least sulfuric acid.

Examples of the “processing liquid containing at least sulfuric acid” other than the SPM liquid may include processing liquids that react (temperature rising or increasing etchant) when mixed with sulfuric acid, such as a diluted sulfuric acid (a mixture of sulfuric acid and water) and a mixture of sulfuric acid and ozone water. The “processing liquid containing at least sulfuric acid” may also be sulfuric acid.

### Overall Configuration of Substrate Processing System

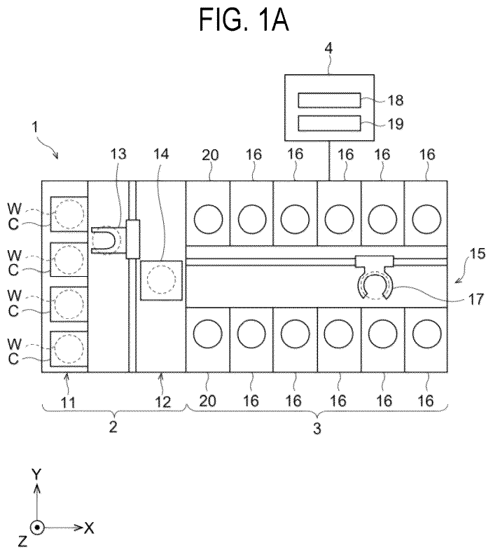

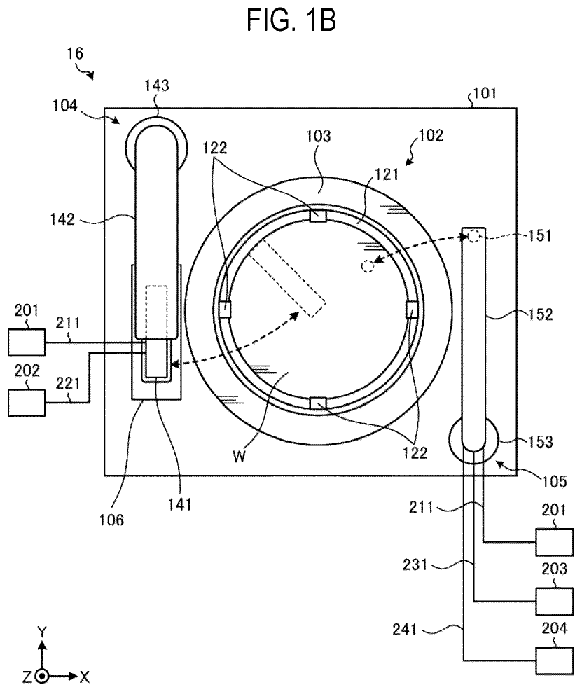

First, an overall schematic configuration of a substrate processing system 1 according to one embodiment of a substrate processing apparatus will be described with reference to FIG. 1A. FIG. 1A is a view showing a schematic configuration of the substrate processing system 1 according to a first embodiment. Hereinafter, for clarification of positional relationships, an X-axis, a Y-axis, and a Z-axis, which are mutually orthogonal, are defined, and a positive direction along the Z-axis is defined as a vertically upward direction.

As shown in FIG. 1A, the substrate processing system 1 (an example of the substrate processing apparatus) includes a load/unload station 2 and a processing station 3.

The load/unload station 2 includes a carrier stage 11 and a transferer 12. A plurality of carriers C (e.g., FOUPs) are placed on the carrier stage 11. Each carrier C accommodates a plurality of substrates (in this embodiment, semiconductor wafers W (hereinafter, for simplicity, simply referred to as “wafers W”)) horizontally with equal intervals in the vertical direction.

A substrate transfer device 13 and a deliverer 14 are provided in the transferer 12. The substrate transfer device 13 is configured as a multi-axis transfer robot or an articulated transfer robot. The substrate transfer device 13 holds wafers by using a fork-shaped wafer holder as an end effector, and transfers the wafer W between the carrier C and the deliverer 14.

The processing station 3 includes a transferer 15 and a plurality of processing units 16.

A substrate transfer device 17 is provided ins the transferer 15. The substrate transfer device 17 is configured as a multi-axis transfer robot or an articulated transfer robot. The substrate transfer device 17 holds the wafer W by using a fork-shaped wafer holder as an end effector, and transfers the wafer W between the deliverer 14 and the processing units 16.

Each processing unit 16 performs liquid processing by supplying a processing liquid (such as the SPM liquid in an example to be described later) to the wafer W loaded thereto by the substrate transfer device 17.

The wafer W accommodated in the carrier C is taken out by the substrate transfer device 13 of the transferer 12 and loaded to the deliverer 14. The wafer W is then taken out by the substrate transfer device 17 of the transferer 15 and loaded to the processing unit 16. After being processed in the processing unit 16, the wafer is returned to the carrier C via a reverse route described above.

The substrate processing system 1 includes a control device 4 (shown only in FIG. 1A). The control device 4 is capable of controlling operations of all operable components included in the substrate processing system 1. The control device 4 is, for example, a computer, and includes a control operator 18 and a storage 19. The storage 19 stores programs (including process recipes that define process sequences) that control various processes executed in the substrate processing system 1. The control operator 18 controls operations of the substrate processing system 1 by reading and executing the programs stored in the storage 19. The control operator 18 may be a central processing unit (CPU) or one or more circuits.

The above-mentioned programs may be recorded on a non-transitory computer-readable storage medium and installed from the storage medium into the storage 19 of the control device 4. Examples of the non-transitory computer-readable storage medium may include a hard disk (HD), a flexible disk (FD), a compact disc (CD), a magneto-optical disc (MO), a memory card, a random access memory (RAM), a read-only memory (ROM), and a solid-state drive (SSD), or a combination of two or more of these.

### Configuration of Processing Unit

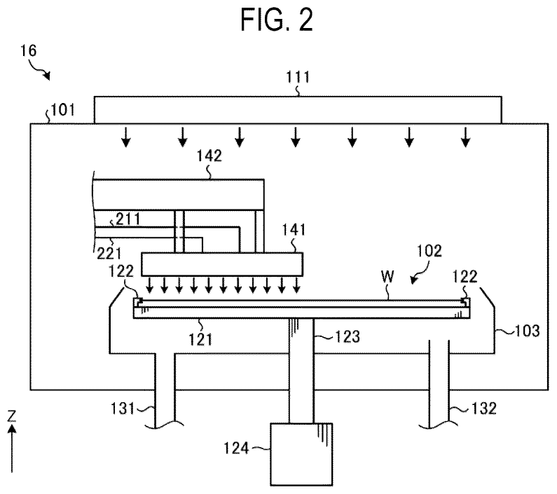

Next, an example configuration of the processing unit 16 incorporated in the substrate processing system 1 will be described with reference to FIGS. 1B and 2. The processing unit 16 includes a chamber 101, a substrate holder 102, a cup 103, a first supplier 104, a second supplier 105, and a nozzle cleaner 106. The processing unit 16 also includes a vapor supply 201, which is a fluid supply that supplies a fluid containing pressurized pure water vapor or mist, an SPM supply 202, which is a processing liquid supply that supplies a processing liquid containing at least sulfuric acid, a rinsing liquid supply 203, and a replacement liquid supply 204. The processing unit 16 removes a resist film formed on a surface of a substrate such as a semiconductor wafer (hereinafter referred to as a “wafer W”).

The substrate holder 102 includes a disk-shaped main body 121 having a diameter larger than the wafer W, a plurality of grips 122 attached to a peripheral portion of an upper surface of the main body 121, a support 123 that supports the main body 121, and a drive 124 that rotates the support 123. The number of grips 122 is not limited to that shown in the figure.

The substrate holder 102 holds the wafer W by gripping a peripheral portion of the wafer W by using the plurality of grips 122. Thus, the wafer W is held horizontally while being slightly spaced apart from the upper surface of the main body 121. As described above, a resist film serving as a target film to be removed (or etched) is formed on a front surface (upper surface) of the wafer W.

In the shown example, the substrate holder 102, which is referred to as a so-called mechanical chuck that grips the peripheral portion of the wafer W by using the plurality of grips 122, is used. Alternatively, a vacuum chuck that holds a back surface of the wafer W by adsorption may be used.

The cup 103 is disposed to surround the substrate holder 102. A drain port 131 for draining the processing liquid supplied to the wafer W to an outside of the chamber 101, and an exhaust port 132 for exhausting an internal atmosphere of the chamber 101 are formed in a bottom of the cup 103.

The first supplier 104 includes a nozzle 141, a first arm 142 extending horizontally and supporting the nozzle 141 from above, and a first rotary lifter 143 configured to rotate and lift the first arm 142. By the first rotary lifter 143, the first arm 142 can move the nozzle 141 between a processing position above the wafer W (indicated by a broken line in FIG. 1B) and a standby position outside the wafer W (indicated by a solid line in FIG. 1B).

The nozzle 141 is a bar nozzle extending linearly along a horizontal direction. The nozzle 141 has a length that is approximately equal to a radius of the wafer W. When disposed at the processing position, a distal end of the nozzle 141 in a longitudinal direction is located above a central portion of the wafer W, and a proximal end of the nozzle 141 in the longitudinal direction is located above the peripheral portion of the wafer W.

The nozzle 141 is connected to the vapor supply 201 via a vapor supply path 211 in which an opening/closing valve 212 is provided. The nozzle 141 is also connected to the SPM supply 202 via an SPM supply path 221. The vapor supply 201 supplies vapor, which is pressurized pure water (deionized water), to the nozzle 141 via the vapor supply path 211. The SPM supply 202 supplies an SPM liquid, which is a mixture of sulfuric acid and hydrogen peroxide, to the nozzle 141 via the SPM supply path 221.

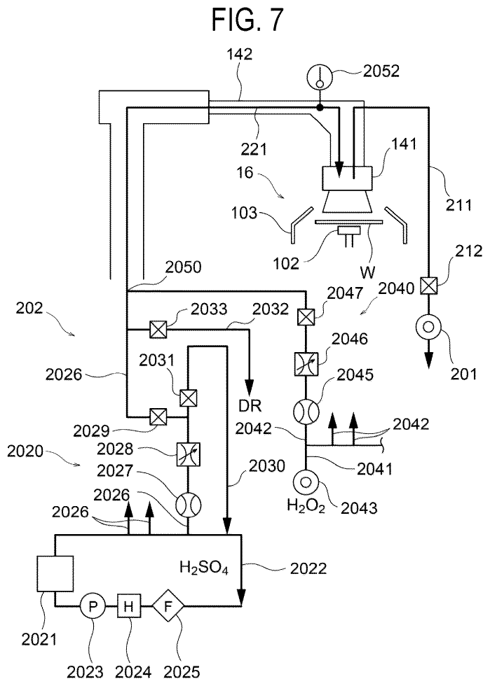

An example configuration of a processing liquid supplier (the vapor supply 201 and the SPM supply 202) that supplies the vapor and the SPM liquid to the nozzle 141 will be described below with reference to FIG. 7.

The SPM supply 202 includes a sulfuric acid supply 2020, a hydrogen peroxide supply 2040, and a mixer 2050 that mixes sulfuric acid and hydrogen peroxide to produce an SPM.

The sulfuric acid supply 2020 includes a tank 2021 that stores sulfuric acid, a circulation path 2022 connected to the tank 2021, and equipment such as a pump 2023, a heater 2024, and a filter 2025, which are provided in the circulation path 2022. The tank 2021 is replenished with sulfuric acid as required, for example, from a sulfuric acid source (not shown) provided as a factory utility. The pump 2023 generates a circulation flow of sulfuric acid, which flows from the tank 2021 into the circulation path 2022 and returns to the tank 2021. The sulfuric acid is heated to a predetermined temperature (e.g., approximately 120 degrees C.) by the heater 2024 and circulates through the circulation path 2022.

The same number of branch supply paths 2026 as that of the processing units 16 provided in the substrate processing system 1 branch from the circulation path 2022, and the branch supply paths 2026 are assigned to the processing units 16 in one-to-one correspondence. Each branch supply path 2026 is provided with a flow meter 2027, a flow control valve 2028, and an opening/closing valve 2029. A return path 2030 branches from the branch supply path 2026 at a location between the flow control valve 2028 and the opening/closing valve 2029. An opening/closing valve 2031 is provided in the return path 2030.

The hydrogen peroxide supply 2040 includes a main supply path 2041 connected to a hydrogen peroxide source 2043 as a factory utility, for example. The same number of branch supply paths 2042 as that of the processing units 16 branch from the main supply path 2041, and the branch supply paths 2042 are assigned to the processing units 16 in one-to-one correspondence. Each branch supply path 2042 is provided with a flow meter 2045, a flow control valve 2046, and an opening/closing valve 2047. A downstream end of the branch supply path 2042 of the hydrogen peroxide supply 2040 merges with the branch supply path 2026 for sulfuric acid. This merging portion serves as the aforementioned mixer 2050, and the branch supply path 2026 on a downstream side of this mixer 2050 serves as the aforementioned SPM supply path 221. A temperature sensor (temperature measurer) 2052 is provided in a downstream end portion of the SPM supply path 221 (near a connection portion with the nozzle 141). A structure for promoting the mixing of sulfuric acid and hydrogen peroxide, such as an in-line mixer, may be provided in the mixer 2050 or in the SPM supply path 221 on a slightly downstream side of the mixer 2050.

A drain line 2032 branches from the branch supply path 2026 for sulfuric acid at a location between the mixer 2050 and the opening/closing valve 2029. The drain line 2032 is provided with an opening/closing valve 2033. This drain line 2032 is used to drain a liquid remaining in the SPM supply path 221. When operating the apparatus without performing a dummy dispense, as will be described in detail later, the drain line 2032 is not used during a normal operation. The drain line 2032 can be used to completely drain the liquid from the SPM supply path 221 during maintenance of the apparatus or when the apparatus is stopped for a long period of time.

The nozzle 141 discharges the SPM liquid supplied from the SPM supply 202 (either alone or mixed with vapor supplied from the vapor supply 201) to the wafer W. A specific configuration of the nozzle 141 will be described later.

The second supplier 105 includes an auxiliary nozzle 151, a second arm 152 extending horizontally and supporting the auxiliary nozzle 151 from above, and a second rotary lifter 153 configured to rotate and lift the second arm 152. By the second rotary lifter 153, the second arm 152 can move the auxiliary nozzle 151 between a processing position above the wafer W and a standby position outside the wafer W.

The auxiliary nozzle 151 is connected to the vapor supply 201 via a vapor supply path 211. The vapor supply 201 supplies vapor to the auxiliary nozzle 151 via the vapor supply path 211. The auxiliary nozzle 151 is connected to the rinsing liquid supply 203 via a rinsing liquid supply path 231 and to the replacement liquid supply 204 via a replacement liquid supply path 241. The rinsing liquid supply 203 supplies a rinsing liquid, in this case, pure water (deionized water) as an example, to the auxiliary nozzle 151 via the rinsing liquid supply path 231. The replacement liquid supply 204 supplies a replacement liquid, in this case, isopropyl alcohol (IPA) as an example, to the auxiliary nozzle 151 via the replacement liquid supply path 241.

The auxiliary nozzle 151 discharges the vapor, which is supplied from the vapor supply 201 via the vapor supply path 211, to the wafer W. The auxiliary nozzle 151 also discharges the rinsing liquid, which is supplied from the rinsing liquid supply 203 via the rinsing liquid supply path 231, to the wafer W. The auxiliary nozzle 151 also discharges the replacement liquid, which is supplied from the replacement liquid supply 204 via the replacement liquid supply path 241, to the wafer W.

The nozzle cleaner 106 is positioned at the standby position of the nozzle 141. The nozzle cleaner 106 cleans the nozzle 141.

### Configuration of Nozzle

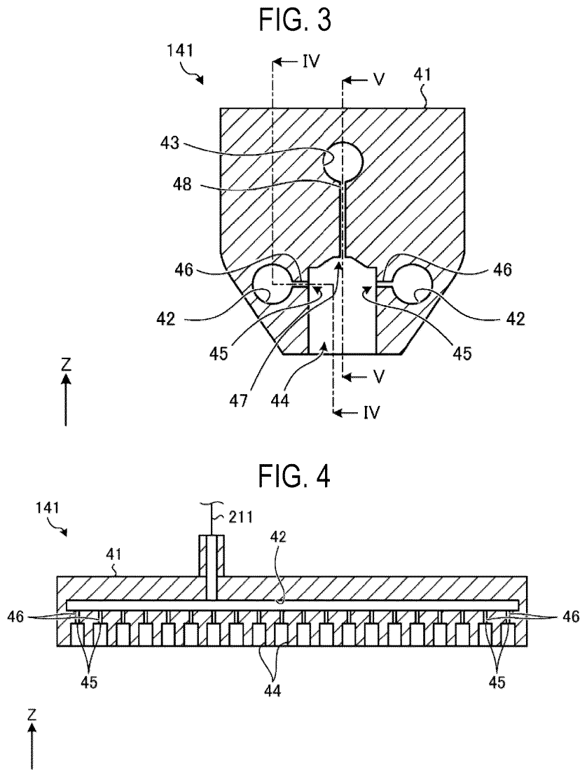

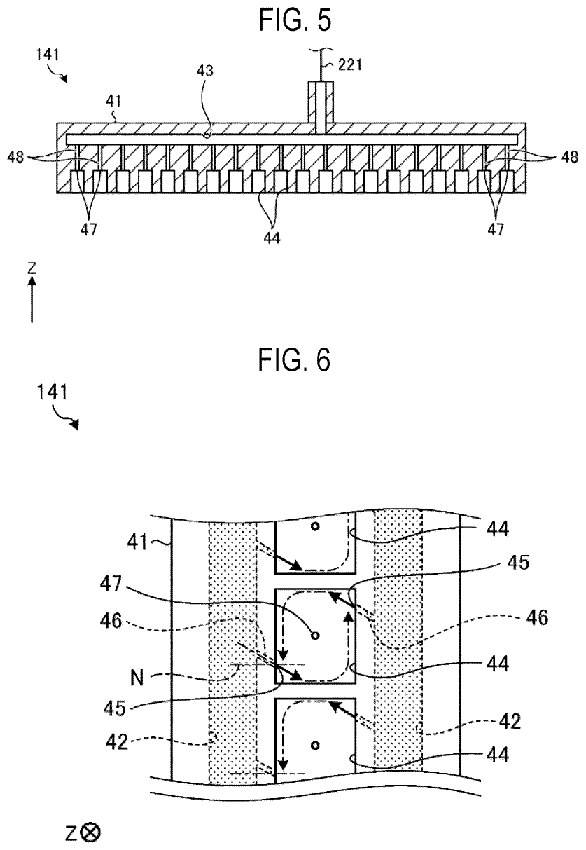

Next, a configuration of the nozzle 141 will be described with reference to FIGS. 3 to 6. FIG. 3 is a cross-sectional view of an example configuration of the nozzle 141 taken along a plane orthogonal to a longitudinal direction. FIG. 4 is a cross-sectional view seen from a direction indicated by arrows IV-IV in FIG. 3. FIG. 5 is a cross-sectional view seen from a direction indicated by arrows V-V in FIG. 3. FIG. 6 is a schematic bottom plan view of the nozzle 141 according to the first embodiment. In FIG. 6, regions in which the vapor flows are indicated by dots.

As shown in FIG. 3, the nozzle 141 includes a nozzle main body 41, two first distribution paths 42, one second distribution path 43, and a plurality of outlet paths 44 (see FIGS. 4 and 5). The nozzle 141 also includes a plurality of first discharge ports 45 and a plurality of first discharge paths 46 (see FIG. 4), and a plurality of second discharge ports 47 and a plurality of second discharge paths 48 (see FIG. 5).

The first distribution paths 42 and the second distribution path 43 are formed inside the nozzle main body 41. As shown in FIGS. 4 and 5, the first distribution paths 42 and the second distribution path 43 extend along a longitudinal direction of the nozzle main body 41. The first distribution paths 42 are connected to the vapor supply 201 via the vapor supply path 211. The second distribution path 43 is connected to the SPM supply 202 via the SPM supply path 221.

As shown in FIG. 3, the second distribution path 43 is disposed on a midline (a line that bisects the nozzle main body 41 into a left-hand side and a right-hand side) of the nozzle main body 41 in a cross-section. Further, the two first distribution paths 42 are disposed on the left-hand side and the right-hand side of the midline of the nozzle main body 41 in the cross-section, respectively.

The plurality of outlet paths 44 are located below the second distribution path 43. As shown in FIGS. 3 to 5, the plurality of outlet paths 44 are flow paths provided in a lower portion of the nozzle main body 41 and extend vertically downward. The plurality of outlet paths 44 are arranged, for example, at equal intervals along the longitudinal direction of the nozzle main body 41. Adjacent outlet paths 44 are separated by a partition wall. A cross-sectional shape of the outlet paths 44 is, for example, rectangular. The cross-sectional shape of the outlet paths 44 may also be circular, elliptical, or the like.

The first discharge port 45 is open in an inner side surface of the outlet path 44. The second discharge port 47 is disposed above the first discharge port 45 and is open in an upper end surface of the outlet path 44. As shown in FIGS. 4 and 5, the plurality of first discharge ports 45 and the plurality of second discharge ports 47 are arranged, for example, at equal intervals along the longitudinal direction of the nozzle main body 41.

As shown in FIGS. 3 to 6, the nozzle 141 includes, in addition to the plurality of first discharge ports 45 and the plurality of second discharge ports 47, the plurality of outlet paths 44 in communication with the two first discharge ports 45 and the one second discharge port 47. The number of first discharge ports 45 and the second discharge ports 47 in communication with a single outlet path 44 is not limited to the number shown in FIGS. 3 to 6. In other words, the nozzle 141 may include a plurality of outlet paths 44 in communication with at least one first discharge port 45 and at least one second discharge port 47.

The plurality of first discharge ports 45 are connected to the first distribution path 42 via the plurality of first discharge paths 46. The plurality of second discharge ports 47 are connected to the second distribution path 43 via the plurality of second discharge paths 48.

The vapor supplied from the vapor supply 201 to the first distribution path 42 is distributed from the first distribution path 42 to the plurality of first discharge paths 46, and discharged from the plurality of first discharge ports 45 to corresponding ones of the plurality of outlet paths 44, respectively. The SPM liquid supplied from the SPM supply 202 to the second distribution path 43 is distributed from the second distribution path 43 to the plurality of second discharge paths 48, and discharged from the plurality of second discharge ports 47 to corresponding ones of the plurality of outlet paths 44, respectively.

The vapor discharged from the first discharge ports 45 and the SPM liquid discharged from the second discharge ports 47 are mixed in a vicinity of an upper end of the outlet path 44, which is an entrance of the outlet path 44, and discharged from a lower end of the outlet path 44, which is an exit of the outlet path 44, toward the wafer W.

As shown in FIG. 6, the second discharge port 47 is disposed coaxially with the outlet path 44 in a plan view. The second discharge port 47 discharges the SPM liquid in a direction along a central axis of the outlet path 44 (i.e., the Z-axis direction). The first discharge port 45 is disposed to face a position offset from the central axis of the outlet path 44 in a plan view. The first discharge port 45 discharges the vapor toward the position offset from the central axis of the outlet path 44 in a plan view. As a result, the vapor colliding with the inner side surface of the outlet path 44 forms a swirling flow of the vapor inside the outlet path 44, and is mixed with the SPM liquid discharged from the second discharge port 47. In order to form the swirling flow of the vapor inside the outlet path 44, the vapor discharged from the first discharge port 45 needs to flow-in along the inner side surface of the outlet path 44.

With the nozzle 141 having the illustrated configuration, it is possible to efficiently mix the vapor and the SPM liquid, and to efficiently increase a temperature of the SPM liquid.

Further, as shown in FIG. 6, a central axis of the first discharge port 45 is inclined with respect to a direction of a normal N to the inner side surface of the outlet path 44 in a plan view. By inclining the central axis of the first discharge port 45 with respect to the direction of the normal N, it is possible to form the swirling flow of the vapor inside the outlet path 44 more easily than when the central axis of the first discharge port 45 is perpendicular to the inner side surface of the outlet path 44. Further, since the swirling flow can lengthen a remaining time of the vapor in the outlet path 44, an amount of vapor used to mix the vapor with the SPM liquid can be reduced.

The nozzle 141 may be configured as shown in FIGS. 3 to 6, but the present disclosure is not limited thereto. Any configuration can be adopted as long as the vapor and the SPM liquid are mixed substantially uniformly inside the nozzle 141 and then the mixed fluid of the vapor and the SPM liquid is discharged from the nozzle 141 to the wafer W.

In addition, in FIG. 7, the temperature sensor 2052 is provided in the SPM supply path 221 near the nozzle 141, but the present disclosure is not limited thereto. The temperature sensor 2052 can be provided at any location as long as the temperature of the SPM immediately before being mixed with the vapor can be measured. For example, the temperature sensor 2052 may be provided so as to measure the temperature of the SPM flowing through the second distribution path 43 inside the nozzle 141.

### Process Performed in Processing Unit

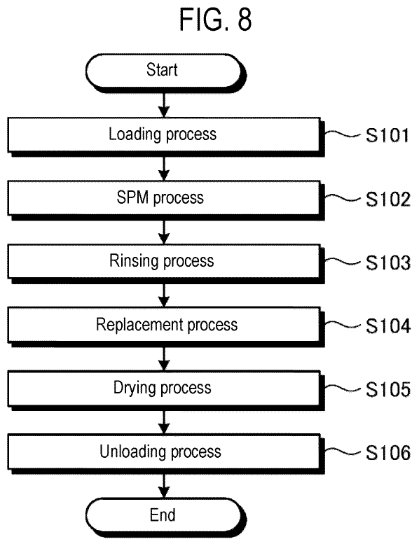

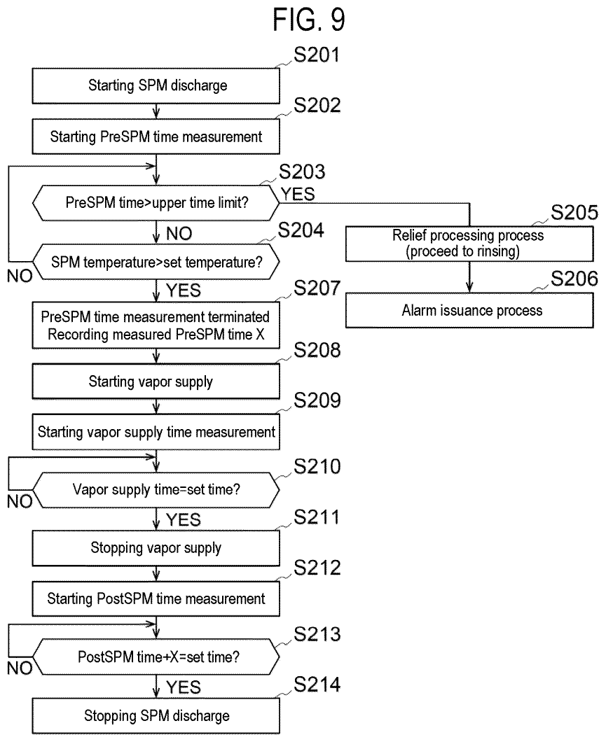

Next, a process performed on a wafer in the processing unit 16 will be described with reference to the flowcharts of FIGS. 8 and 9. The process described below is also performed under control of the control device 4 shown in FIG. 1A.

First, a loading process for the wafer W is performed (step S101). Specifically, the substrate transfer device 17 of the transferer 15 loads the wafer W into the processing unit 16, and the wafer W is held by the substrate holder 102. Thereafter, the substrate holder 102 starts rotating at a predetermined rotational speed. Until a series of processes for a single wafer W is completed, the wafer W continuously rotates (the rotational speed may vary).

Subsequently, an SPM process for the wafer W is performed (step S102). The first rotary lifter 143 moves the nozzle 141 from the standby position to the processing position above the wafer W. Thereafter, the nozzle 141 discharges the SPM liquid or the mixed fluid of the SPM liquid and the vapor to the surface of the wafer W. Thus, the resist film formed on the surface of the wafer W is removed. Details of step S102 will be described later with reference to FIG. 9.

The auxiliary nozzle 151 may be used in the SPM process. When using the auxiliary nozzle 151, the second rotary lifter 153 positions the auxiliary nozzle 151 above the wafer W. Specifically, since the supply of vapor from the nozzle 141 only may be insufficient, the auxiliary nozzle 151 is positioned, for example, above an outer peripheral portion of the wafer W. Thereafter, the vapor is discharged from the auxiliary nozzle 151 to the surface of the wafer W. By using the auxiliary nozzle 151 as described above, it is possible to supply the vapor to an entire surface of the wafer W more evenly. Therefore, the temperature of the SPM liquid can be increased more evenly across the entire surface of the wafer W.

Once the SPM process in step S102 is completed, a rinsing process is performed (step S103). In the rinsing process, the auxiliary nozzle 151 is positioned above the central portion of the wafer W, and the rinsing liquid (here, DIW, that is, pure water) is supplied from the auxiliary nozzle 151 to the surface of the wafer W. The rinsing liquid supplied to the wafer W spreads and flows toward a periphery of the wafer W due to a centrifugal force generated by the rotation of the wafer W, and then, are scattered outward from the wafer W. As a result, the SPM liquid remaining on the wafer W is washed away by the rinsing liquid. During the rinsing process, a landing position of the rinsing liquid may be moved between the central portion and the peripheral portion of the wafer.

Subsequently, a replacement process is performed (step S104). In the replacement process, a replacement liquid (IPA) is supplied from the auxiliary nozzle 151 to a central portion of the surface of the wafer W. The replacement liquid supplied to the wafer W spreads and flows toward the periphery of the wafer W due to a centrifugal force generated by the rotation of the wafer W, and thus, the rinsing liquid remaining on the wafer W is replaced with the replacement liquid.

Subsequently, a drying process is performed (step S105). In the drying process, the discharge of the replacement liquid is stopped, and a rotation number of the wafer W is increased. As a result, the replacement liquid remaining on the wafer W is shaken off, and the wafer W is dried. Thereafter, the rotation of the wafer W stops.

Subsequently, an unloading process is performed (step S106). In the unloading process, the substrate transfer device 17 of the transferer 15 unloads the wafer W held by the substrate holder 102 from the processing unit 16. This completes the series of processes performed on a single wafer W in the processing unit 16.

### Details of SPM Process

Next, details of the SPM process (step 102 described above) according to one embodiment will be described.

First, the nozzle 141 is moved from the standby position to the processing position above the wafer W. At this time point, most sections in the SPM supply path 221 are empty as a result of a suck-back process (which will be described in detail later) performed after a previous process, that is, after step S214 to be described later. The SPM liquid used in the previous process remains in a section from the mixer 2050 to a slightly downstream side of the mixer 2050 in the SPM supply path 221. In addition, the SPM liquid that could not be completely removed by the suck-back process remains in the nozzle 141. A temperature of the SPM supply path 221 drops, particularly in the empty sections, due to heat dissipation according to a time elapsed after the previous process ends.

In this state, the opening/closing valves 2029 and 2047 are opened, and the opening/closing valve 2031 is closed. The opening/closing valve 2033 is kept closed continuously. Thus, sulfuric acid and hydrogen peroxide flow from the branch supply paths 2026 and 2042 into the mixer 2050 and are mixed to form an SPM liquid, and then the SPM liquid flows into the SPM supply path 221. Further, the SPM liquid remaining in the above-mentioned section in the SPM supply path 221 is pushed out by the new SPM liquid. As a result, only the SPM liquid (the SPM liquid without being mixed with the vapor) is discharged from the nozzle 141 to the substrate (step S201).

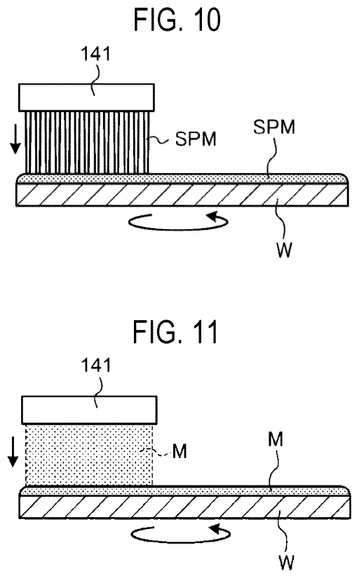

This state is shown schematically in FIG. 10, in which the SPM liquid is being discharged from each outlet path 44 of the nozzle 141 toward the surface of the wafer W. The SPM liquid landing on the surface of the wafer W in rotation covers the entire surface of the wafer W. Discharging only the SPM liquid from the nozzle 141 before discharging the mixed fluid of the SPM liquid and the vapor from the nozzle 141, as described above, is referred to as “PreSPM discharge.” As the SPM liquid passes through the SPM supply path 221, the SPM liquid loses heat by a cool pipe constituting the SPM supply path 221 and the nozzle 141. Thereafter, the SPM liquid is discharged from the nozzle 141 to the wafer W. As time passes from a start of discharging the SPM liquid from the nozzle 141, temperatures of the pipe and the nozzle 141 rise, and the temperature of the SPM liquid discharged from the nozzle 141 approaches a desired temperature.

Simultaneously with the start of the PreSPM discharge, measurement (count-up) of a PreSPM time, which is a time elapsed from the start of the PreSPM discharge, is started (step S202). This measurement is performed by using a timer function of the control device 4. For example, a time during which the opening/closing valve 2029 is open can be considered as the PreSPM time. Other time measurements, which will be described later, can also be measured based on a timing at which a specific opening/closing valve is opened or closed.

Subsequently, whether or not the measured PreSPM time exceeds an upper time limit is determined (step S203). As long as the SPM source is operating normally, the PreSPM time hardly exceeds the upper time limit.

When the determination result in step S203 is “YES,” it is determined that a process by the mixed fluid under normal process conditions cannot be expected from then on, and the process transitions to a process of relief processing the wafer W that is currently being processed (step S205). In addition, an alarm is issued via a user interface to notify an operator that abnormality has occurred (step S206).

The relief processing process of step S205 is, for example, as follows. First, the SPM liquid is stopped from being supplied to the nozzle 141. Subsequently, a rinsing process (the same process as step S103 described above) is performed. Thereafter, the same processes as the replacement process S104 and the drying process S105 described above are performed. Thereafter, the wafer W is inspected, and in a case where the wafer W needs to undergo relief processing, for example, the SPM process is performed again on the wafer W.

On the other hand, when the determination result in step S203 is “NO,” the temperature of the SPM liquid detected by the temperature sensor 2052 is sampled with a predetermined sampling rate, and the sampled temperature measurement value is compared with a predetermined set temperature (step S204).

The set temperature may be, for example, 140 degrees C (but is not limited thereto) when a temperature of the sulfuric acid supplied from the sulfuric acid supply 2020 (i.e., a temperature of the sulfuric acid circulating through the circulation path 2022) is 120 degrees C and a temperature of the hydrogen peroxide supplied from the hydrogen peroxide supply 2040 is room temperature.

When the sampled (measured) temperature measurement value exceeds the set temperature (“YES” in step S204), the measurement (count-up) of the PreSPM time is terminated, and the measured PreSPM time (i.e., the time elapsed from the start of the PreSPM discharge (also referred to as time “X”)) is stored in a memory (e.g., the storage 19 of the control device 4) (step S207).

When the determination result in step S204 is “NO,” the process returns to step S203. That is, a loop constituted by steps S203 and S204 is repeated until the determination result in step S204 is “YES.” When the determination result in step S204 fails to become “YES” even when the PreSPM time reaches the upper time limit, it is determined that abnormality has occurred as described above, and the flow exits the loop and transitions to steps S205 and S206 as described above.

When the measured SPM temperature exceeds the set temperature, the opening/closing valve 212 is immediately opened to start supplying vapor (pure water vapor) to the nozzle 141 (step S208), and measurement (count-up) of a time (vapor supply time) elapsed from the start of the vapor supply is started (step S209). The vapor supplied to the nozzle 141 is mixed with the SPM liquid inside the nozzle 141 to form a mixed fluid, and the mixed fluid is then discharged from the nozzle 141 to the wafer W. This state is shown schematically in FIG. 11, in which a mixed fluid M is being discharged from each outlet path 44 of the nozzle 141 toward the surface of the wafer W. The mixed fluid M landing on the surface of the wafer W in rotation covers the entire surface of the wafer W. Thus, an etching target on the surface of the wafer W is rapidly etched.

Subsequently, whether or not the measured vapor supply time (corresponding to a time during which the mixed fluid is discharged to the wafer W) reaches a set arrival time (step S210).

When the vapor supply time reaches the set arrival time, the opening/closing valve 212 is immediately closed to stop the supply of the vapor to the nozzle 141 (step S211). Thus, the nozzle 141 discharges only the SPM liquid to the wafer W again. A state in this time is the same as the PreSPM discharge shown in FIG. 10. Discharging only the SPM liquid from the nozzle 141 after discharging the mixed fluid of the SPM liquid and the vapor from the nozzle 141, as described above, is also referred to as “PostSPM discharge.” Measurement (count-up) of a PostSPM time, which is a time elapsed from a start of the PostSPM discharge (i.e., a time elapsed from the stop of the vapor supply), is started (step S212).

A sum of the PostSPM time, which is being measured, and the PreSPM time (the time X mentioned above) recorded in the memory is compared with a predetermined set time (step S213). When the sum reaches the set time (“YES” in step S213), the opening/closing valves 2029 and 2047 are closed to stop the discharge of SPM liquid from the nozzle 141 (step S214). Further, simultaneously with closing the opening/closing valve 2029, the opening/closing valve 2031 is opened to circulate the high-temperature sulfuric acid, which is introduced from the circulation path 2022 to the branch supply path 2026, back to the circulation path 2022 via the return path 2030. Thus, the temperature of the branch supply path 2026 is prevented from being dropped. This completes a series of the SPM process for a single wafer W (step S102 in FIG. 8). Thereafter, the process transitions to the rinsing process of step S103 in FIG. 8.

The set time with respect to the sum of the PostSPM time and the PreSPM time used in step S213 may also be used as the upper time limit of the PreSPM time, which serves as a reference in the determination in step S203.

In one example in which the apparatus has been in a standby mode for a long period of time and the SPM liquid has cooled in the piping significantly, the PreSPM time, the vapor supply time, and the PostSPM time may be 10 seconds, 60 seconds, and 10 seconds, respectively. On the other hand, when the apparatus is processing the wafer W continuously (with short processing intervals), the PreSPM time, the vapor supply time, and the PostSPM time may be 5 seconds, 60 seconds, and 15 seconds, respectively.

, In addition, after step S214, the aforementioned suck-back process is performed. The suck-back process is performed by closing the opening/closing valves 2029 and 2047 and then opening the opening/closing valve 2033. Thus, undischarged SPM liquid remaining in the nozzle 141 and the SPM supply path 221 is drained by gravity via the drain line 2032. In general, the suck-back process is performed so that the SPM liquid remains on the slightly downstream side of the mixer 2050 (a position slightly above the mixer 2050 in FIG. 7) and an inside of the SPM supply path 221 on a downstream side of the aforementioned position becomes empty. At this time, some amount of SPM liquid may remain in the nozzle 141 due to liquid drainage. By the suck-back process, a discharge amount of degraded SPM liquid to the wafer can be suppressed.

According to the above embodiment, the following advantageous effects can be achieved.

In the above embodiment, the vapor is mixed with the SPM liquid and the mixed fluid of the SPM liquid and the vapor is discharged to the wafer, after the temperature of the SPM liquid reaches the set temperature. Thus, it is possible to precisely control, from immediately after discharge, a temperature of the mixed fluid to be an intended temperature, and to achieve an intended value of an etching amount of the target film on the wafer. Therefore, when a plurality of wafers is processed, variation in the etching amount can be suppressed, and inter-plane uniformity in the etching amount can be improved. The term “inter-plane uniformity” refers to a degree of variation in processing results (e.g., etching amounts) of wafers W when the same processing is performed on the wafers W.

In addition, in the above embodiment, there exist time periods during which only the SPM liquid is discharged to the wafer (specifically, the PreSPM time and the PostSPM time), and the target film on the wafer is also etched during these time periods. However, an etching amount when only the SPM liquid is discharged to the wafer is significantly smaller than that when the mixed fluid is discharged. Therefore, even when the etching by the SPM liquid only is performed before and/or after the etching by the mixed fluid, influence of the etching by the SPM liquid only on a total etching amount is quite small. This is evident from an example of experimental results to be described below.

### Example of Experimental Results

Hereinafter, results of an experiment for comparing an etching amount when only an SPM liquid is discharged to a wafer and an etching amount when a mixed fluid is discharged to the wafer will be described. An etching target film was SiN. A composition of the SPM liquid was sulfuric acid:hydrogen peroxide=10:1. A temperature of the sulfuric acid before being mixed with hydrogen peroxide was 120 degrees C. An etching time was 60 seconds for both Condition 1 and Condition 2.

(Condition 1) Only the SPM liquid was supplied to the nozzle 141 and discharged to the wafer from the nozzle 141. The etching amount in this case was 0.06 nm.

(Condition 2) In addition to supplying the SPM liquid under the same conditions as Condition 1, water vapor was supplied to the nozzle 141 at pressures of 28 kPa, 47 kPa, and 55 kPa, and a mixed fluid was discharged from the nozzle 141 to the wafer. The etching amount was 0.39 nm when the water vapor pressure was 28 kPa, 0.51 nm when the water vapor pressure was 47 kPa, and 0.54 nm when the water vapor pressure was 55 kPa.

From the above experimental results, it can be also recognized that even when the PreSPM discharge (discharging only the SPM liquid to the wafer W) is performed before the etching by the mixed fluid (e.g., Condition 2), influence of the PreSPM discharge on the total etching amount is quite small. It should be noted here that since the SPM liquid cooled inside the pipe is discharged to the substrate in the PreSPM discharge, influence of the PreSPM discharge on the total etching amount is further reduced than that estimated from the above experimental results. Further, since the PreSPM time is, for example, approximately 10 seconds and a mixed fluid discharge time is, for example, approximately 60 seconds (these discharge times are merely examples), the influence of the PreSPM discharge on the total etching amount is further reduced. Therefore, in terms of required inter-wafer uniformity in etching amount (i.e., a limit of allowable variation in the etching amounts of wafers), the etching amount by the PreSPM discharge can be ignored. In other words, the PostSPM discharge performed in the specific embodiment described above can be omitted.

However, when it is necessary to control the inter-wafer uniformity in the etching amount strictly, the PostSPM discharge, which is performed in the specific embodiment described above, may be performed, and the sum of the PreSPM time and the PostSPM time may be set to a predetermined set time. Although the etching amount during the PreSPM discharge and the PostSPM discharge is significantly smaller than the etching amount during the mixed fluid discharge, by controlling the sum of the PreSPM time and the PostSPM time, the inter-wafer uniformity of the etching amount can be further improved. Further, it is possible to prevent a processing schedule (time required to process a single wafer) from becoming unusual.

Strictly speaking, the temperature of the SPM liquid during the PreSPM discharge is lower than the temperature of the SPM liquid during the PostSPM discharge. Further, a temperature of the wafer during the PreSPM discharge is lower than a temperature of the wafer during the PostSPM discharge. Therefore, an etching rate during the PostSPM discharge is slightly higher than an etching rate during the PreSPM discharge. Therefore, a sum of PreSPM time+α×PostSPM time (α is a constant, for example, approximately 1 to 1.2) may be kept constant.

In addition, according to the above embodiment, it is not necessary to perform a dummy dispense of the SPM liquid, which is necessary in a conventional method. In the conventional methods, an SPM liquid, which remains in a pipe connected to a nozzle during a discharge standby time (a time period between a completion of discharging the SPM liquid to a single wafer and a start of discharging the SPM liquid to a next wafer) and is cooled, is purged by using heated sulfuric acid and discharged to an appropriate dummy dispense port. The dummy dispense port is generally located below or near a home position of the nozzle. Further, after the sulfuric acid in the pipe is drained via a drain line, the nozzle is moved to a processing position above the wafer and a mixed fluid of the SPM liquid and water vapor is discharged to the wafer. In this case, a significant amount of processing liquid (SPM liquid and sulfuric acid) is wasted. In addition, costs for disposing the wasted liquid are incurred. Further, since it takes a relatively long time from a start of the dummy dispense to a start of discharging the mixed fluid to the wafer W, throughput is reduced.

In contrast, according to the above embodiment, a waste amount of processing liquid, that is, an amount of consumed processing liquid, can be reduced. In the above embodiment, during the PreSPM discharge, the SPM liquid having a temperature slightly lower than the set temperature is supplied to the wafer without being mixed with water vapor. Even though the etching amount during the PreSPM discharge is significantly smaller than the etching amount during the mixed fluid discharge as described above, the etching target film is still etched during the PreSPM discharge to some extent. Therefore, the SPM liquid is not completely wasted. Further, in the above embodiment, the nozzle 141 can be moved to the processing position to start the process immediately after the wafer is set on the substrate holder. Thus, time consumption that may occur in the case of performing the dummy dispense can be saved, which improves throughput of the apparatus.

The substrate to be processed is not limited to a semiconductor wafer, but may be any type of substrate, such as a glass substrate and a ceramic substrate, which is used in the technical field of semiconductor device manufacturing.

According to the present disclosure, it is possible to suppress variations in etching amount.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method,
wherein the substrate processing method is performed by using a substrate processing apparatus comprising:
a substrate holder configured to hold a substrate;
a fluid supply configured to supply a fluid containing pressurized pure water vapor or mist;
a processing liquid supply configured to supply a processing liquid containing at least sulfuric acid;
a nozzle connected to the fluid supply and the processing liquid supply, and configured to mix and discharge the fluid and the processing liquid to the substrate; and
a temperature measurer configured to measure a temperature of the processing liquid supplied from the processing liquid supply to the nozzle, and
wherein the substrate processing method comprises:
a processing liquid discharge process of supplying the processing liquid from the processing liquid supply to the nozzle and discharging the processing liquid from the nozzle to the substrate; and
after the processing liquid discharge process, a mixed fluid discharge process of supplying the fluid from the fluid supply to the nozzle and discharging a mixed fluid, which is obtained by mixing the fluid and the processing liquid, from the nozzle to the substrate, when the temperature of the processing liquid measured by the temperature measurer reaches a specified temperature.

2. The substrate processing method of claim 1, further comprising an alarm issuance process of issuing an alarm when the temperature of the processing liquid measured by the temperature measurer fails to reach the specified temperature even after a specified time has elapsed from a start of discharging the processing liquid to the substrate in the processing liquid discharge process.

3. The substrate processing method of claim 2, further comprising a relief processing process of stopping the discharge of the processing liquid from the nozzle to the substrate and relief processing the substrate when the alarm is issued.

4. The substrate processing method of claim 3, wherein the relief processing process includes rinsing the substrate with deionized water (DIW).

5. The substrate processing method of claim 1, wherein the mixed fluid discharge process is performed for a predetermined period of time, and after the predetermined period of time elapses, the supply of the fluid from the fluid supply to the nozzle is stopped.

6. The substrate processing method of claim 5, further comprising, after the supply of the fluid from the fluid supply to the nozzle is stopped, a processing liquid discharge process of continuously supplying the processing liquid from the processing liquid supply to the nozzle and discharging the processing liquid from the nozzle to the substrate.

7. The substrate processing method of claim 6, wherein the processing liquid discharge process before the mixed fluid discharge process is a first processing liquid discharge process and the processing liquid discharge process after the mixed fluid discharge process is a second processing liquid discharge process, and
wherein the second processing liquid discharge process is performed until a total time of a discharge time of the processing liquid in the first processing liquid discharge process and a discharge time of the processing liquid in the second processing liquid discharge process reaches a preset time.

8. The substrate processing method of claim 7, further comprising an alarm issuance process of issuing an alarm when the temperature of the processing liquid measured by the temperature measurer fails to reach the specified temperature even after a specified time has elapsed from a start of discharging the processing liquid to the substrate in the first processing liquid discharge process,
wherein the preset time of the total time is used, in the alarm issuance process, as the specified time that serves as a reference for determining whether or not to issue the alarm.

9. The substrate processing method of claim 1, wherein the processing liquid is a liquid mixture of sulfuric acid and hydrogen peroxide.

10. A substrate processing apparatus comprising:
a substrate holder configured to hold a substrate;
a fluid supply configured to supply a fluid containing pressurized pure water vapor or mist;
a processing liquid supply configured to supply a processing liquid containing at least sulfuric acid;
a nozzle connected to the fluid supply and the processing liquid supply, and configured to mix and discharge the fluid and the processing liquid to the substrate;
a temperature measurer configured to measure a temperature of the processing liquid supplied from the processing liquid supply to the nozzle; and
a controller configured to control operations of the substrate processing apparatus,
wherein the controller is further configured to cause the substrate processing apparatus to perform a substrate processing method including:
a processing liquid discharge process of supplying the processing liquid from the processing liquid supply to the nozzle and discharging the processing liquid from the nozzle to the substrate; and
after the processing liquid discharge process, a mixed fluid discharge process of supplying the fluid from the fluid supply to the nozzle and discharging a mixed fluid, which is obtained by mixing the fluid and the processing liquid, from the nozzle to the substrate, when the temperature of the processing liquid measured by the temperature measurer reaches a specified temperature.

11. The substrate processing apparatus of claim 10, wherein the controller is further configured to cause the substrate processing apparatus to perform an alarm issuance process of issuing an alarm when the temperature of the processing liquid measured by the temperature measurer fails to reach the specified temperature even after a specified time has elapsed from a start of discharging the processing liquid to the substrate in the processing liquid discharge process.

12. The substrate processing apparatus of claim 11, wherein the controller is further configured to cause the substrate processing apparatus to perform a relief processing process of stopping the discharge of the processing liquid from the nozzle to the substrate and relief processing the substrate when the alarm is issued.

13. The substrate processing apparatus of claim 12, wherein the relief processing process includes rinsing the substrate with deionized water (DIW).

14. The substrate processing apparatus of claim 10, wherein the mixed fluid discharge process is performed for a predetermined period of time, and after the predetermined period of time elapses, the supply of the fluid from the fluid supply to the nozzle is stopped.

15. The substrate processing apparatus of claim 14, wherein the controller is further configured to cause the substrate processing apparatus to perform, after the supply of the fluid from the fluid supply to the nozzle is stopped, a processing liquid discharge process of continuously supplying the processing liquid from the processing liquid supply to the nozzle and discharging the processing liquid from the nozzle to the substrate.

16. The substrate processing apparatus of claim 15, wherein the processing liquid discharge process before the mixed fluid discharge process is a first processing liquid discharge process and the processing liquid discharge process after the mixed fluid discharge process is a second processing liquid discharge process, and
wherein the controller is further configured to cause the substrate processing apparatus to perform the second processing liquid discharge process until a total time of a discharge time of the processing liquid in the first processing liquid discharge process and a discharge time of the processing liquid in the second processing liquid discharge process reaches a preset time.

17. The substrate processing apparatus of claim 16, wherein the controller is further configured to cause the substrate processing apparatus to perform an alarm issuance process of issuing an alarm when the temperature of the processing liquid measured by the temperature measurer fails to reach the specified temperature even after a specified time has elapsed from a start of discharging the processing liquid to the substrate in the first processing liquid discharge process, and
wherein the preset time of the total time is used, in the alarm issuance process, as the specified time that serves as a reference for determining whether or not to issue the alarm.

18. A non-transitory computer-readable storage medium storing a program for controlling operations of a substrate processing apparatus, which includes: a substrate holder configured to hold a substrate; a fluid supply configured to supply a fluid containing pressurized pure water vapor or mist; a processing liquid supply configured to supply a processing liquid containing at least sulfuric acid; a nozzle connected to the fluid supply and the processing liquid supply, and configured to mix and discharge the fluid and the processing liquid to the substrate; a temperature measurer configured to measure a temperature of the processing liquid supplied from the processing liquid supply to the nozzle; and a controller,
wherein the controller is configured to execute the program to cause the substrate processing apparatus to perform a substrate processing method including:
a processing liquid discharge process of supplying the processing liquid from the processing liquid supply to the nozzle and discharging the processing liquid from the nozzle to the substrate; and
after the processing liquid discharge process, a mixed fluid discharge process of supplying the fluid from the fluid supply to the nozzle and discharging a mixed fluid, which is obtained by mixing the fluid and the processing liquid, from the nozzle to the substrate, when the temperature of the processing liquid measured by the temperature measurer reaches a specified temperature.
